(19) United States
(12) Patent Application Publication
(10) Pub. No.: US 2025/0212659 A1
(43) Pub. Date: Jun. 26, 2025

(54) ENCAPSULATING COMPOSITION FOR ORGANIC LIGHT EMITTING DIODE AND DEVICE THEREFROM

(71) Applicant: DUK SAN NEOLUX CO., LTD., Cheonan-si (KR)

(72) Inventors: Jun BAE, Cheonan-si (KR); Changmin LEE, Cheonan-si (KR); Yeon Soo LEE, Cheonan-si (KR); Jin Hyun KIM, Cheonan-si (KR); Ju Cheol KWON, Cheonan-si (KR); Kyung Soo KIM, Cheonan-si (KR)

(73) Assignee: DUK SAN NEOLUX CO., LTD., Cheonan-si (KR)

(21) Appl. No.: 18/989,863

(22) Filed: Dec. 20, 2024

(30) Foreign Application Priority Data
Dec. 20, 2023 (KR) 10-2023-0187786
Jun. 28, 2024 (KR) 10-2024-0085852

(51) Int. Cl. H10K 59/80; B05D 3/06; C09D 4/00; C09D 7/40; C09D 7/61; C09D 133/08; C09D 133/10; H10K 59/40; H10K 102/00

(52) U.S. Cl. CPC H10K 59/873; C09D 4/00; C09D 7/61; C09D 7/70; C09D 133/08; C09D 133/10; H10K 59/40; B05D 3/067; B05D 2502/00; B05D 2601/22; H10K 2102/351

(57) ABSTRACT

Provided is an encapsulating composition for an organic light emitting diode, which includes a photoinitiator; a first photocurable monomer; and a second photocurable monomer, wherein the first and the second photocurable monomers do not include silicone or aromatic hydrocarbon, and an encapsulating composition having low permittivity and high film hardness suitable for an ink-jetting process is prepared, thereby providing a display device having a high sensitivity touch sensor.

### BACKGROUND

### Field

The present disclosure relates to an encapsulating composition for an organic light-emitting diode and an organic light-emitting diode display device prepared from the same.

### Related Art

An organic light-emitting diode display device is a display device that self-emits light when current is supplied. However, when it comes into contact with external moisture or oxygen, its light-emitting characteristics deteriorate and its lifespan shortens; therefore, an encapsulating material must be used to protect the light-emitting material from external moisture and oxygen.

The encapsulating material is a multilayer structure composed of inorganic and organic layers, in which the inorganic layer may be formed using the chemical vapor deposition method using plasma, the atomic layer deposition method, or physical sputtering, and the organic layer may be formed using the ink-jetting or vacuum evaporation deposition method.

The organic layer serves to block or cover defects or particles that may be created when the inorganic layer is formed. Recently, these organic layers are formed using ink-jetting and photocuring processes, and the viscosity, spreadability, and vapor pressure of the photocurable composition used in the organic layer are important. The encapsulating layer is formed under the touch sensor of the display device, and the performance of the touch sensor is determined by the permittivity of the encapsulating material, and particularly, the low permittivity of materials used in organic layers with relatively high permittivity is being considered as an important factor. Since it acts as an encapsulating material, a certain level of film hardness is required.

### PRIOR ART DOCUMENT

### Patent Document

(Patent Document 1) Chinese Patent No. 107155328

### SUMMARY

An embodiment of the present disclosure is to provide a display device of an organic light-emitting element having a high-sensitivity touch sensor by providing an encapsulating composition having low permittivity and high film hardness suitable for an inkjet process.

It is preferable that the encapsulating composition according to the present disclosure includes a photoinitiator; a first photocurable monomer represented by Formula 1 below; and a second photocurable monomer represented by Formula 2 below.

Y₁—X₁—Y₂ [Formula 1]
wherein in Formula 1 above,
X₁ is a C₂₋₃₀ alkylene group,
Y₁ and Y₂ are Formula 3,

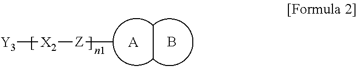

wherein in Formula 2 above,
Y₃ is Formula 3,
Z is —O— or a —NH— group,
X₂ is a C₁₋₃₀ alkylene group,
A is a C₃₋₃₀ alicyclic group,
B is a ring group including at least one double bond of C₃₋₃₀,
A ring and the B ring are fused together,
n₁ is an integer of 0 to 5,

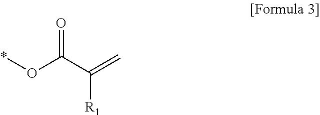

wherein in Formula 3 above,
* is a connection part,
R₁ is hydrogen or a methyl group,
the X₁, X₂, Y₁ to Y₃, and R₁ may each be further substituted with one or more substituents selected from the group consisting of deuterium; a halogen; a C₁₋₃₀ alkyl group; a boron group; a germanium group; a cyano group; an amino group; a nitro group; a C₁₋₃₀ alkylthio group; a C₁₋₃₀ alkoxy group; a fluorenyl group; a C₂₋₃₀ heterocyclic group including at least one heteroatom among O, N, S, Si, and P; a C₃₋₃₀ alicyclic group; and a combination thereof, and may form a ring between the neighboring substituents.

It is preferable that the first photocurable monomer includes 1,2-ethandiol diacrylate, 1,3-propanediol diacrylate, 1,4-butanediol diacrylate, 1,5-pentanediol diacrylate, 1,6-hexanediol diacrylate, 1,7-heptanediol diacrylate, 1,8-octanediol diacrylate, 1,9-nonaendiol diacrylate, 1,10-decanediol diacrylate, 1,11-undecanediol diacrylate, 1,12-dodecanediol diacrylate, 1,13-tridecanediol diacrylate, 1,14-tetradecanediol diacrylate, 1,15-pentadecanediol diacrylate, 1,2-ethandiol dimethacrylate, 1,3-propanediol dimethacrylate, 1,4-butanediol dimethacrylate, 1,5-pentanediol dimethacrylate, 1,6-hexanediol dimethacrylate, 1,7-heptanediol dimethacrylate, 1,8-octanediol dimethacrylate, 1,9-nonaendiol dimethacrylate, 1,10-decanediol dimethacrylate, 1,11-undecanediol dimethacrylate, 1,12-dodecanediol dimethacrylate, 1,13-tridecanediol dimethacrylate, 1,14-tetradecanediol dimethacrylate, 1,15-pentadecanediol dimethacrylate, 2,3-propanediol diacrylate, 2,4-butanediol diacrylate, 3,4-butanediol diacrylate, 2,5-pentanediol diacrylate, 4,5-pentanediol diacrylate, 2,6-hexanediol diacrylate, 4,6-hexanediol diacrylate, 2,7-heptanediol diacrylate, 5,7-heptanediol diacrylate, 2,8-octanediol diacrylate, 6,8-octanediol diacrylate, 2,9-nonaendiol diacrylate, 7,9-nonaendiol diacrylate, 2,10-decanediol diacrylate, 8,10-decanediol diacrylate, 3,12-dodecanediol diacrylate, 11,12-dodecanediol diacrylate, 5,15-pentadecanediol diacrylate, 10,15-pentadecanediol diacrylate, 2,3-propanediol dimethacrylate, 2,4-butanediol dimethacrylate, 3,4-butanediol dimethacrylate, 2,5-pentanediol dimethacrylate, 4,5-pentanediol dimethacrylate, 2,6-hexanediol dimethacrylate, 4,6-hexanediol dimethacrylate, 2,7-heptanediol dimethacrylate, 5,7-heptanediol dimethacrylate, 2,8-octanediol dimethacrylate, 6,8-octanediol dimethacrylate, 2,9-nonaendiol dimethacrylate, 7,9-nonaendiol dimethacrylate, 2,10-decanediol dimethacrylate, 8,10-decanediol dimethacrylate, 2,12-dodecanediol dimethacrylate, 6,12-dodecanediol dimethacrylate, 10,12-dodecanediol dimethacrylate, 2,15-pentadecanediol dimethacrylate, 7,15-pentadecanediol dimethacrylate, 12,15-pentadecanediol dimethacrylate, or a combination thereof.

It is preferable that the A ring of the second photocurable monomer includes an alicyclic group selected from three- to six-membered rings; the B ring includes a carbon ring group selected from three- to six-membered rings including at least one double bond within the ring; wherein the A ring and the B ring may be further substituted with one or more substituents selected from a C₁₋₃₀ alkyl group; and may form a ring between the neighboring substituents.

It is preferable that the second photocurable monomer includes T-1 to T-50 below or a combination thereof.

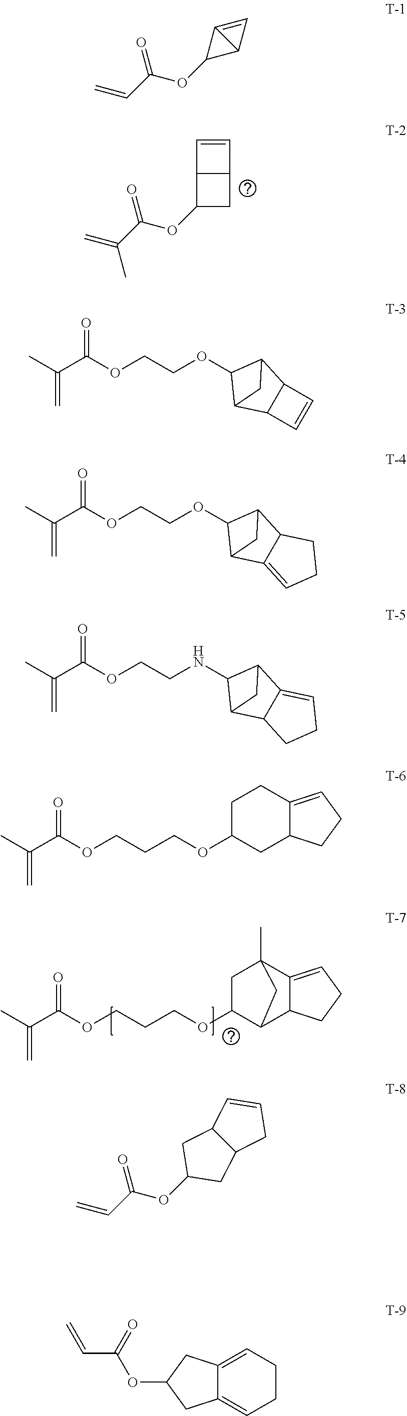

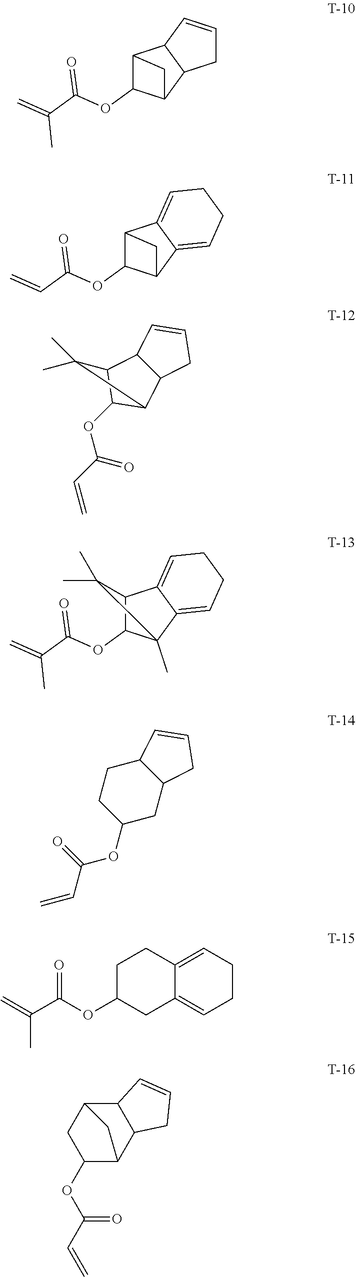

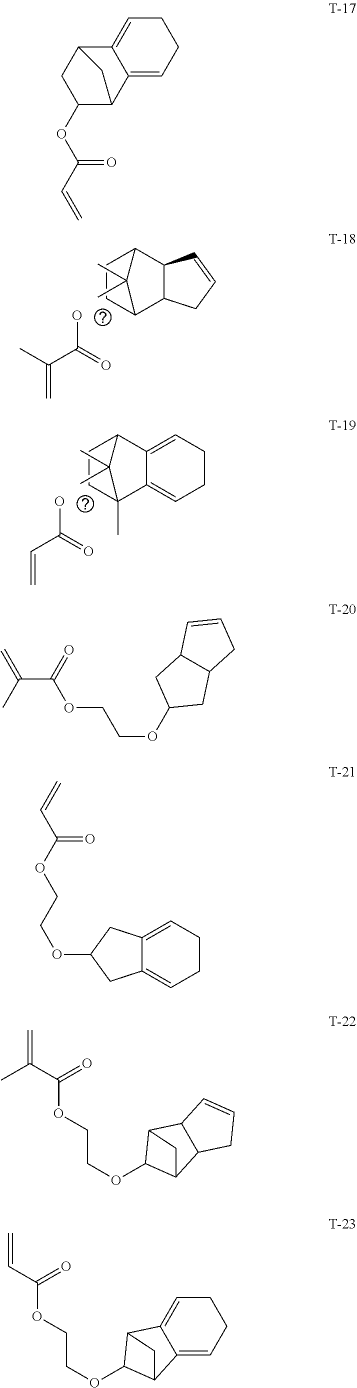

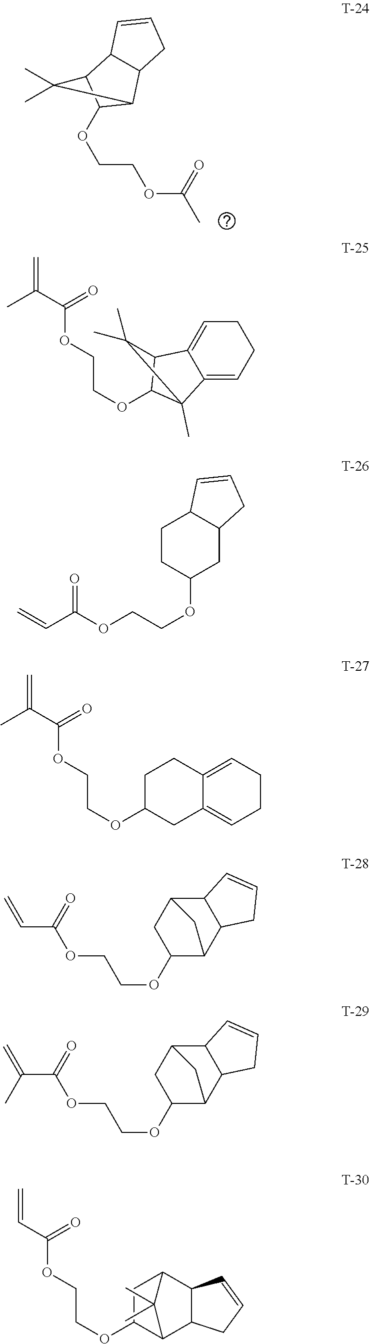

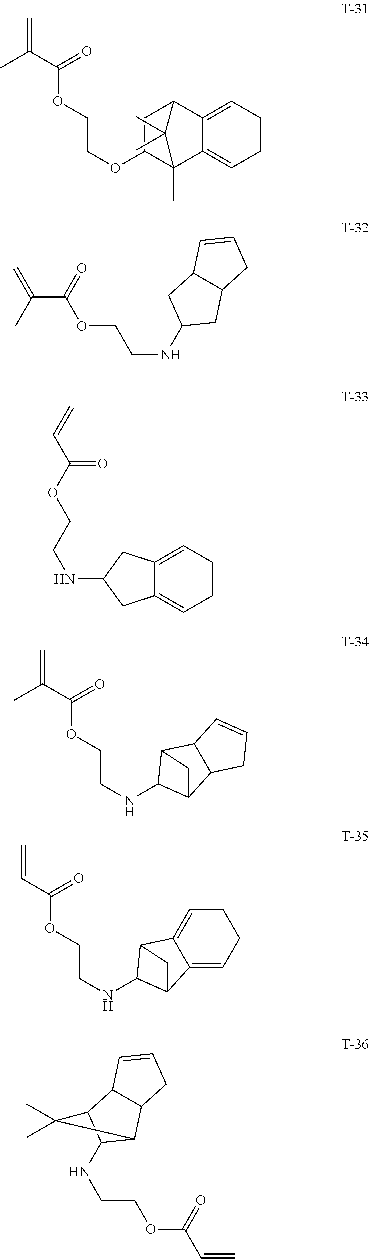 [SMILES: C=C(C)C(=O)OCCOC1CC2C3=CCCC=C3C1(C)C2(C)C ; C=C(C)C(=O)OCCNC1CC2C=CCC2C1 ; C=CC(=O)OCCNC1CC2=CCCC=C2C1 ; C=C(C)C(=O)OCCNC1C2CC1C1CC=CC12 ; C=CC(=O)OCCNC1C2CC1C1=CCCC=C12 ; C=CC(=O)OCCNC1C2C3C=CCC3C1C2(C)C]

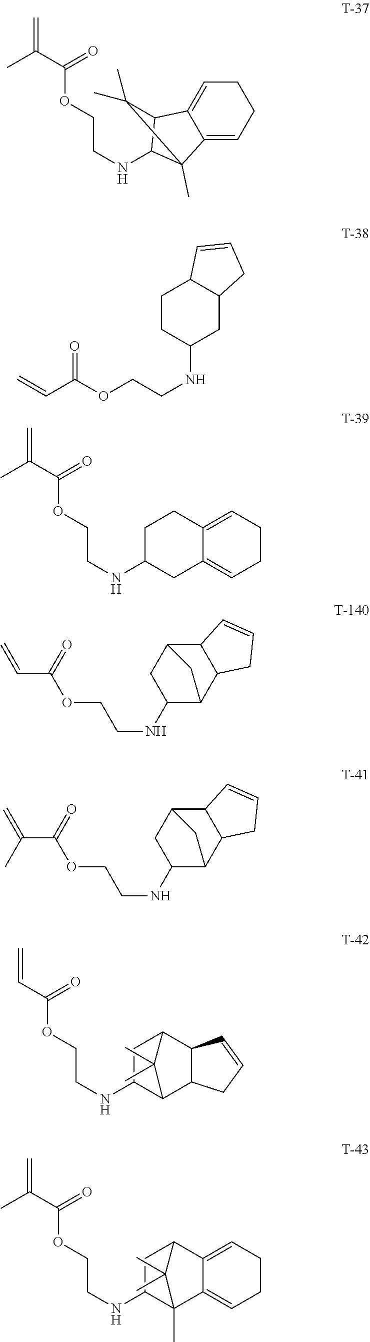

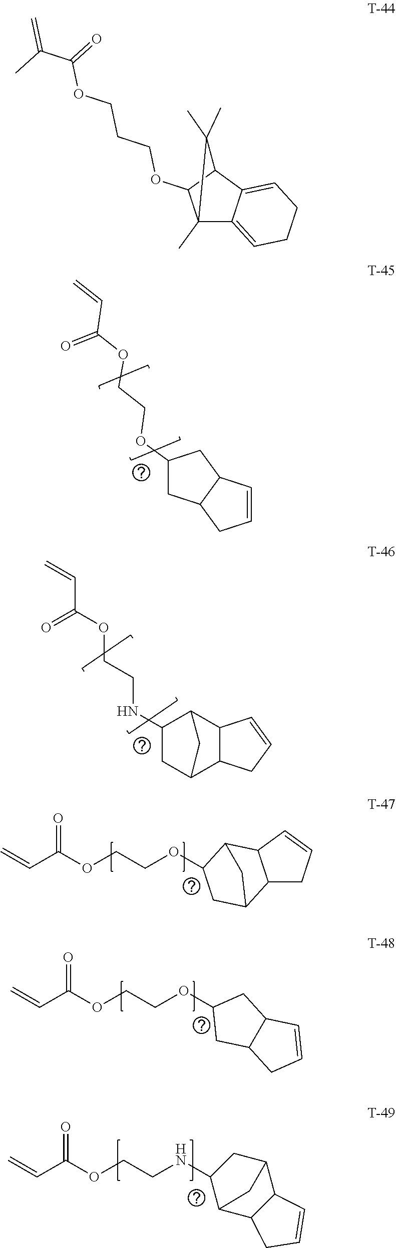

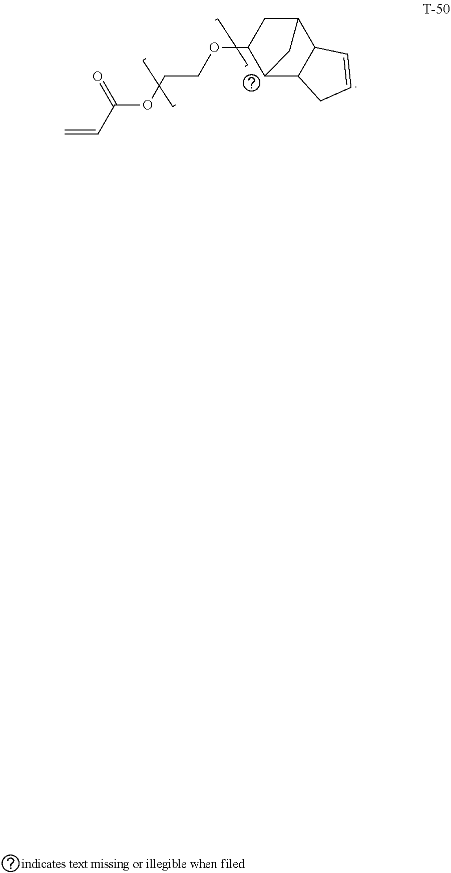

It is preferable that the encapsulating composition further includes hollow silica particles.

It is preferable that the encapsulating composition includes the hollow silica particles in an amount of 0.1 wt % to 10 wt %.

It is preferable that the size of the hollow silica particle is 30 nm to 100 nm.

It is preferable that the first photocurable monomer is included in an amount of 40 to 80 parts by weight relative to 100 parts by weight of the encapsulating composition.

It is preferable that the second photocurable monomer is comprised in an amount of 20 to 60 parts by weight relative to 100 parts by weight of the encapsulating composition.

It is preferable that the surface tension of the encapsulating composition is 20 mN/m to 40 mN/m at 25° C.

In another aspect of the present disclosure, an encapsulating film, which is prepared by applying and coating; and photocuring the encapsulating composition, may be provided.

In the encapsulating film, it is preferable that an ink head, which ink-jets the encapsulating composition of the present disclosure with a drop size of 2 pL to 40 pL, is used.

It is preferable that the thickness of the encapsulating film is 3 μm to 15 μm.

It is preferable that the transmittance of the encapsulating film is 90% to 99% at a wavelength of 550 nm.

It is preferable that the permittivity of the encapsulating film is 0.1 F/m to 3.2 F/m at a frequency from 1 kHz to 300 kHz.

It is preferable that the modulus of the encapsulating film is 1,000 MPa to 5,000 MPa.

In still another aspect of the present disclosure, an organic barrier layer including the encapsulating composition may be provided.

In still another aspect of the present disclosure, a display device including the organic barrier layer may be provided.

In still another aspect of the present disclosure, an electronic device, which includes the display device; and a control unit for driving the display device, may be provided.

### Effect of Invention

An object of the present disclosure is to provide a display device of an organic light-emitting diode, which, while not including a silicon group in the photocurable monomer, and not including an aromatic hydrocarbon, satisfies the permittivity of 3.2 F/m or less at 1 kHz, 100 kHz, and 300 kHz; the modulus of 1,000 Mpa or more; and the transmittance of 90% or more at a wavelength of 550 nm, thereby having a high-sensitivity touch sensor.

That is, when the modulus is below 1,000 Mpa, the hardness becomes poor and cracks occur due to an external impact, which causes the penetration of moisture and oxygen thereby affecting the organic light-emitting diode; whereas when the permittivity exceeds 3.2 F/m, the sensitivity of the touch sensor may decrease.

### DESCRIPTION OF EXEMPLARY EMBODIMENTS

Hereinafter, exemplary embodiments of the present disclosure will be described in detail. However, these exemplary embodiments are presented for illustration purposes, and the present disclosure is not limited by the same, and the present disclosure is only defined by the scope of the claims described below. Each component is described in detail below.

It is preferable that the encapsulating composition according to the present disclosure includes a photoinitiator; a first photocurable monomer represented by Formula 1 below; and a second photocurable monomer represented by Formula 2 below.

### (1) Photocurable Monomer

The first photocurable monomer of the present disclosure may be represented by Formula 1 below, and the second photocurable monomer may be a photocurable monomer represented by Formula 2.

Y₁—X₂—Y₂ [Formula 1]
wherein in Formula 1 above,
X₁ is a C₂₋₃₀ alkylene group,
Y₁ and Y₂ are Formula 3,

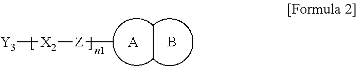

wherein in Formula 2 above,
Y₃ is Formula 3,
Z is —O— or a —NH— group,
X₂ is a C₁₋₃₀ alkylene group,
A is a C₃₋₃₀ alicyclic group,
B is a ring group including at least one double bond of C₃₋₃₀,
A ring and the B ring are fused together,
n₁ is an integer of 0 to 5,

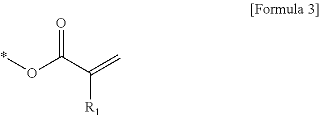

wherein in Formula 3 above,
is a connection part,
R₁ is hydrogen or a methyl group,
the X₁, X₂, Y₁ to Y₃, and R₁ may each be further substituted with one or more substituents selected from the group consisting of deuterium; a halogen; a C₁₋₃₀ alkyl group; a boron group; a germanium group; a cyano group; an amino group; a nitro group; a C₁₋₃₀ alkylthio group; a C₁₋₃₀ alkoxy group; a fluorenyl group; a C₂₋₃₀ heterocyclic group including at least one heteroatom among O, N, S, Si, and P; a C₃₋₃₀ alicyclic group; and a combination thereof, and may form a ring between the neighboring substituents.

Examples of the first photocurable monomer having a structure similar to Formula 1 above may include 1,2-ethandiol diacrylate, 1,3-propanediol diacrylate, 1,4-butanediol diacrylate, 1,5-pentanediol diacrylate, 1,6-hexanediol diacrylate, 1,7-heptanediol diacrylate, 1,8-octanediol diacrylate, 1,9-nonaendiol diacrylate, 1,10-decanediol diacrylate, 1,11-undecanediol diacrylate, 1,12-dodecanediol diacrylate, 1,13-tridecanediol diacrylate, 1,14-tetradecanediol diacrylate, 1,15-pentadecanediol diacrylate, 1,2-ethandiol dimethacrylate, 1,3-propanediol dimethacrylate, 1,4-butanediol dimethacrylate, 1,5-pentanediol dimethacrylate, 1,6-hexanediol dimethacrylate, 1,7-heptanediol dimethacrylate, 1,8-octanediol dimethacrylate, 1,9-nonaendiol dimethacrylate, 1,10-decanediol dimethacrylate, 1,11-undecanediol dimethacrylate, 1,12-dodecanediol dimethacrylate, 1,13-tridecanediol dimethacrylate, 1,14-tetradecanediol dimethacrylate, 1,15-pentadecanediol dimethacrylate, 2,3-propanediol diacrylate, 2,4-butanediol diacrylate, 3,4-butanediol diacrylate, 2,5-pentanediol diacrylate, 4,5-pentanediol diacrylate, 2,6-hexanediol diacrylate, 4,6-hexanediol diacrylate, 2,7-heptanediol diacrylate, 5,7-heptanediol diacrylate, 2,8-octanediol diacrylate, 6,8-octanediol diacrylate, 2,9-nonaendiol diacrylate, 7,9-nonaendiol diacrylate, 2,10-decanediol diacrylate, 8,10-decanediol diacrylate, 3,12-dodecanediol diacrylate, 11,12-dodecanediol diacrylate, 5,15-pentadecanediol diacrylate, 10,15-pentadecanediol diacrylate, 2,3-propanediol dimethacrylate, 2,4-butanediol dimethacrylate, 3,4-butanediol dimethacrylate, 2,5-pentanediol dimethacrylate, 4,5-pentanediol dimethacrylate, 2,6-hexanediol dimethacrylate, 4,6-hexanediol dimethacrylate, 2,7-heptanediol dimethacrylate, 5,7-heptanediol dimethacrylate, 2,8-octanediol dimethacrylate, 6,8-octanediol dimethacrylate, 2,9-nonaendiol dimethacrylate, 7,9-nonaendiol dimethacrylate, 2,10-decanediol dimethacrylate, 8,10-decanediol dimethacrylate, 2,12-dodecanediol dimethacrylate, 6,12-dodecanediol dimethacrylate, 10,12-dodecanediol dimethacrylate, 2,15-pentadecanediol dimethacrylate, 7,15-pentadecanediol dimethacrylate, 12,15-pentadecanediol dimethacrylate, or a combination thereof, and may preferably include 1,2-ethandiol diacrylate, 1,3-propanediol diacrylate, 1,4-butanediol diacrylate, 1,5-pentanediol diacrylate, 1,6-hexanediol diacrylate, 1,7-heptanediol diacrylate, 1,8-octanediol diacrylate, 1,9-nonaendiol diacrylate, 1,10-decanediol diacrylate, 1,11-undecanediol diacrylate, 1,12-dodecanediol diacrylate, 1,13-tridecanediol diacrylate, 1,14-tetradecanediol diacrylate, 1,15-pentadecanediol diacrylate, 1,2-ethandiol dimethacrylate, 1,3-propanediol dimethacrylate, 1,4-butanediol dimethacrylate, 1,5-pentanediol dimethacrylate, 1,6-hexanediol dimethacrylate, 1,7-heptanediol dimethacrylate, 1,8-octanediol dimethacrylate, 1,9-nonaendiol dimethacrylate, 1,10-decanediol dimethacrylate, 1,11-undecanediol dimethacrylate, 1,12-dodecanediol dimethacrylate, 1,13-tridecanediol dimethacrylate, 1,14-tetradecanediol dimethacrylate, 1,15-pentadecanediol dimethacrylate, or a combination thereof, but are not limited thereto.

The A ring of the second photocurable monomer may include an alicyclic group selected from three- to six-membered rings; the B ring may include a carbon ring group selected from three- to six-membered rings including at least one double bond within the ring; wherein the A ring and the B ring may be further substituted with one or more substituents selected from a C₁₋₃₀ alkyl group; and may form a ring between the neighboring substituents.

Examples of the photocurable monomers having a structure of Formula 2 above may include, T-1 to T-50 below or a combination thereof but are not limited thereto.

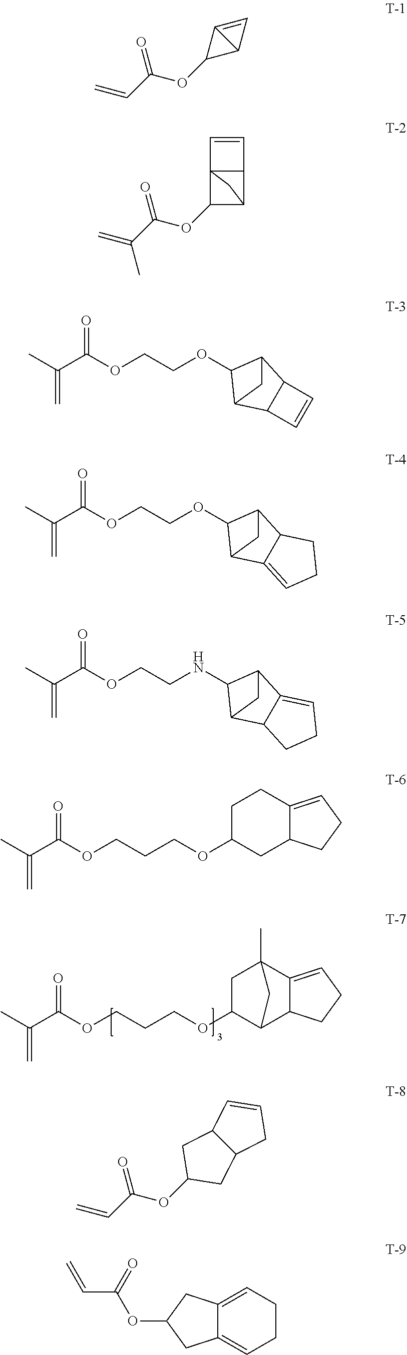

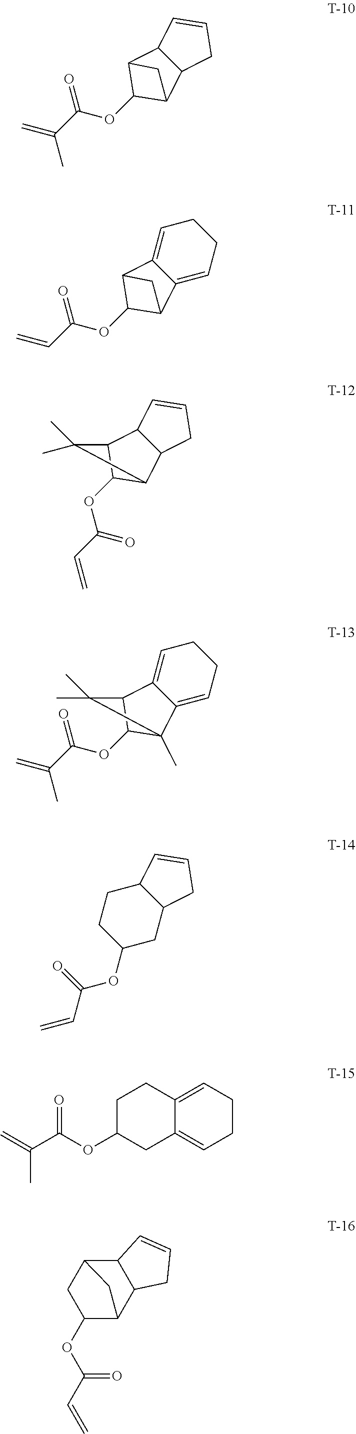

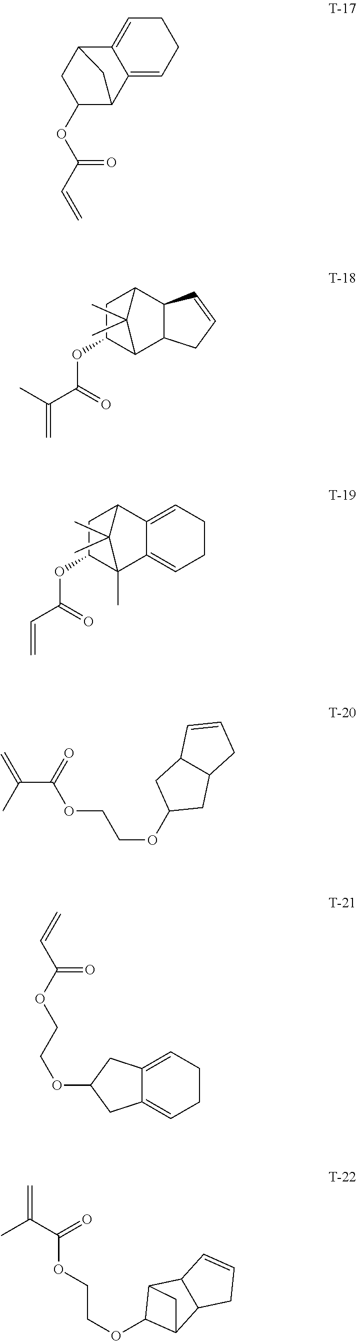

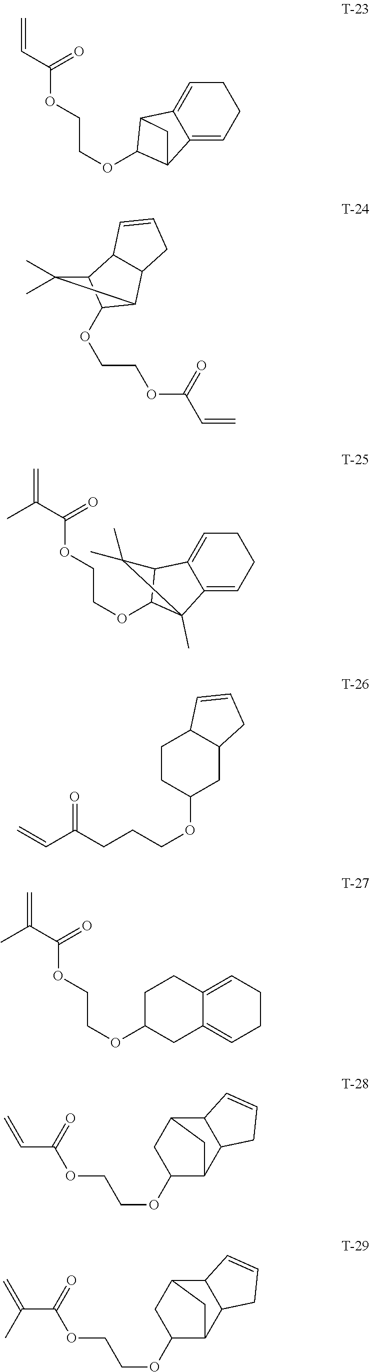

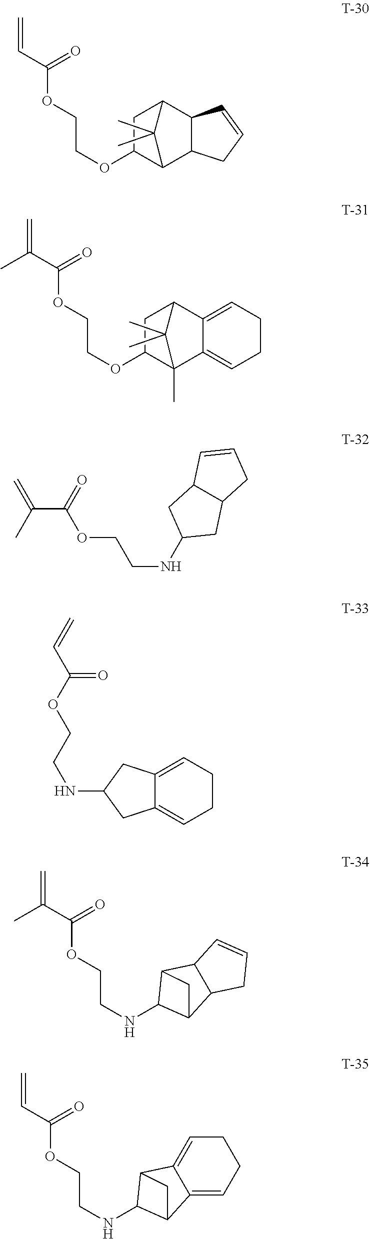

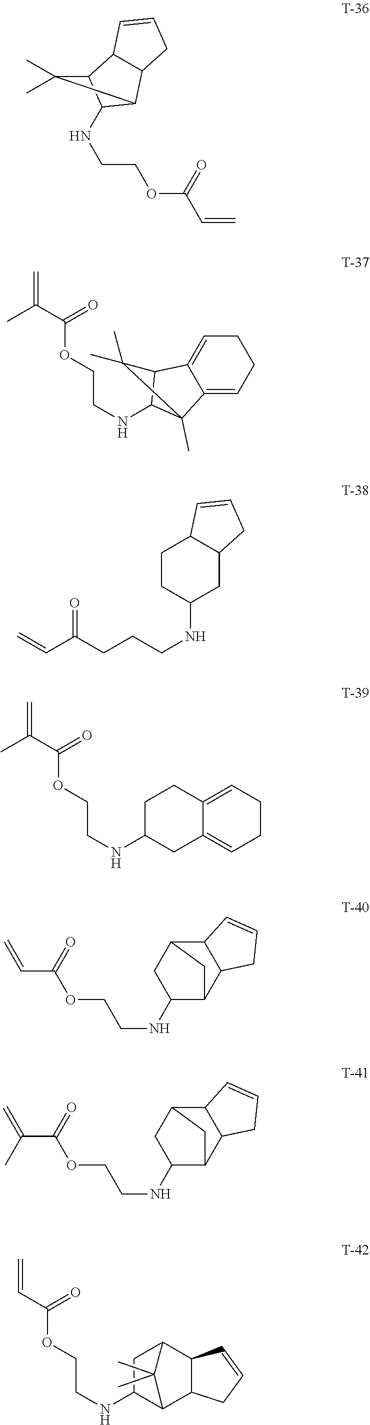

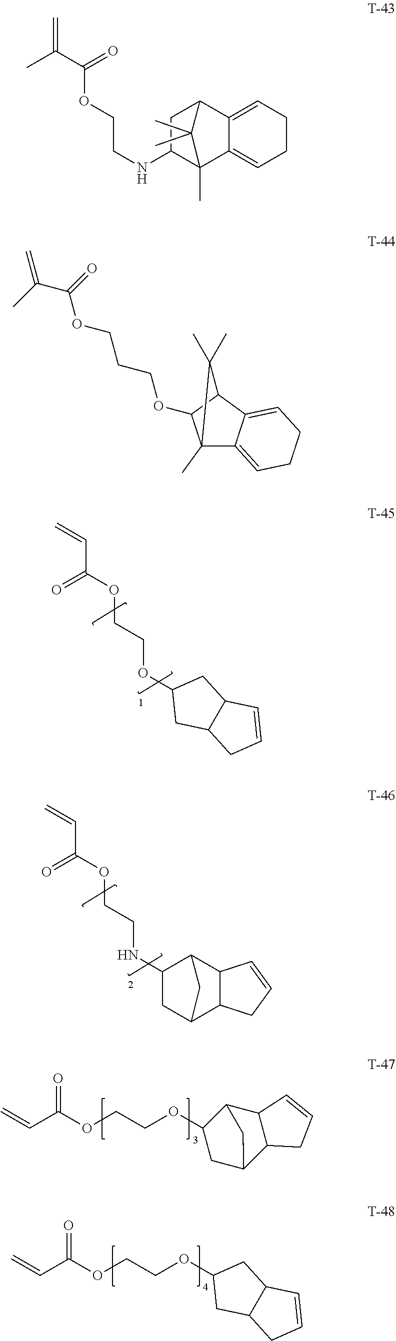

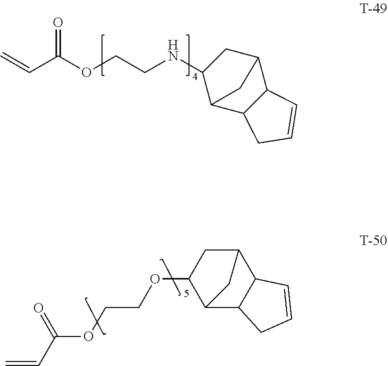

The “alkylene group” refers to a radical of a C₁₋₃₀ saturated aliphatic functional group connected by a single bond, including a straight-chain alkyl group, a branched-chain alkyl group, a cycloalkyl (alicyclic) group, an alkyl-substituted cycloalkyl group, and a cycloalkyl-substituted alkyl group.

The “aliphatic” refers to a C₁₋₃₀ aliphatic hydrocarbon unless otherwise stated, but is not limited thereto.

The “vinyl group” refers to a —CH═CH2- functional group.

The first photocurable monomer and the second photocurable monomer of the encapsulating composition of the present disclosure do not include silicone and aromatic hydrocarbon. Photocurable monomers including silicone have an aromatic group and thus have high permittivity, whereas photocurable monomers without an aromatic group have a difficulty in forming sufficiently high film hardness. The photocurable composition of the encapsulating material for an organic light-emitting device used in the present disclosure may have low permittivity and sufficient film hardness by using a first photocurable monomer and a second photocurable monomer having the structures of Formula 1 and Formula 2 above.

The first photocurable monomer may be included in an amount of 40 parts by weight to 80 parts by weight, preferably 40 parts by weight to 75 parts by weight, and more preferably 50 parts by weight to 75 parts by weight based on 100 parts by weight of the encapsulating composition.

The second photocurable monomer may be contained in an amount of 20 parts by weight to 60 parts by weight, preferably 20 parts by weight to 50 parts by weight, and more preferably 20 parts by weight to 40 parts by weight based on 100 parts by weight of the encapsulating composition.

The encapsulating composition may further include hollow silica particles.

The hollow silica particles may be included in an amount of 0.1 wt % to 10 wt % based on the total amount of an encapsulating composition.

It is preferable that the size of the hollow silica particles is 30 nm to 100 nm.

For the spreadability and jetting properties of the encapsulating composition, the surface tension at 25° C. may be 20 mN/m to 40 mN/m, preferably 25 mN/m to 38 mN/m.

### (2) Photoinitiator

In order to perform photocuring, a photoradical initiator must be used. The photoinitiator may be used alone or in combination of two or more types.

The photopolymerization initiator may include a triazine-based initiator, an acetophenone-based initiator, a benzophenone-based initiator, a thioxanthone-based initiator, a benzoin-based initiator, a phosphorus-based initiator, an oxime-based initiator, or a mixture thereof.

Examples of the triazine-based compound may include 2,4,6-trichloro-s-triazine, 2-phenyl 4,6-bis(trichloromethyl)-s-triazine, 2-(3′,4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloromethyl)-s-triazine; 2-biphenyl 4,6-bis(trichloromethyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-trichloromethyl(piperonyl)-6-triazine, 2-4-trichloromethyl(4′-methoxystyryl)-6-triazine, etc.

Examples of the acetophenone-based compound may include 2,2′-diethoxy acetophenone, 2,2′-dibutoxy acetophenone, 2-hydroxy-2-methylpropiophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, etc.

Examples of the benzophenone-based compound may include benzophenone, benzoyl benzoate, methyl benzoyl benzoate, 4-phenyl benzophenone, hydroxy benzophenone, acrylated benzophenone, 4,4′-bis(dimethylamino)benzophenone, 4,4′-bis(diethylamino)benzophenone, 4,4′-dimethylaminobenzophenone, 4,4′-dichlorobenzophenone, 3,3′-dimethyl-2-methoxybenzophenone, etc.

Examples of the thioxanthone-based compound may include thioxanthone, 2-chlorothioxanthone, 2-methylthioxanthone, isopropyl thioxanthone, 2,4-diethyl thioxanthone, 2,4-diisopropyl thioxanthone, 2-chlorothioxanthone, etc.

Examples of the benzoin-based compound may include benzoin, benzoin methyl ether, benzoin ethyl ether, benzoin isopropyl ether, benzoin isobutyl ether, benzyldimethyl ketal, etc.

Examples of the phosphorus-based compound may include diphenyl(2,4,6-trimethylbenzoyl)phosphine oxide, benzyl(diphenyl)phosphine oxide, TPO (BASF) or a mixture thereof. For example, when a phosphoric acid initiator is used, the composition of the present disclosure may exhibit better initiation performance under long-wave UV.

Examples of the oxime-based compound may include 1-[4-(phenylthio)phenyl]-1,2-octanedion-2-(O-benzoyloxime), 1-[({1-[9-ethyl-6-(2-methylbenzoyl)-9H-carbazol-3-yl]ethylidin}amino)oxy]-1-(O-acetyloxime)ethanone, 1-[ethyl-6-{2-methyl-4-(2,2-dimethyl-1,3-dioxolanyl)methoxybenzoyl}-9H-carbazol-3-yl]ethanone, 1-[4-[3-[4-[[2-acetyloxy]ethyl]sulfonyl]-2-methylbenzoyl]-6-[1-[(acetyloxy)imino]ethyl]-9H-carbazol-9-yl]phenyl-1-(O-acetyloxime)octanone, etc.

As the photoinitiator, a carbazole-based compound, a diketone-based compound, a sulfonium borate-based compound, a diazo-based compound, an imidazole-based compound, or a non-imidazole-based compound may be used in addition to the compounds described above.

As the photoinitiator, which is a radical polymerization initiator, a peroxide-based compound, an azobis-based compound, etc. may be used.

Examples of the peroxide-based compound may include ketone peroxides such as methyl ethyl ketone peroxide, methyl isobutyl ketone peroxide, cyclohexanone peroxide, methylcyclohexanone peroxide, acetylacetone peroxide, etc.; diacyl peroxides such as isobutyryl peroxide, 2,4-dichlorobenzoyl peroxide, o-methylbenzoyl peroxide, bis-3,5,5-trimethylhexanoyl peroxide, etc.; hydroperoxides such as 2,4,4,-trimethylpentyl-2-hydroperoxide, diisopropylbenzene hydroperoxide, cumene hydroperoxide, t-butyl hydroperoxide, etc.; dialkyl peroxides such as dicumyl peroxide, 2,5-dimethyl-2,5-di(t-butylperoxy)hexane, 1,3-bis(t-butyloxyisopropyl)benzene, t-butylperoxyvalerate n-butyl ester, etc.; alkyl peresters such as 2,4,4-trimethylpentyl peroxyphenoxyacetate, α-cumyl peroxyneodecanoate, t-butyl peroxybenzoate, di-t-butyl peroxytrimethyl adipate, etc.; and percarbonates such as di-3-methoxybutyl peroxydicarbonate, di-2-ethylhexyl peroxydicarbonate, bis-4-t-butylcyclohexyl peroxydicarbonate, diisopropyl peroxydicarbonate, acetylcyclohexylsulfonyl peroxide, t-butyl peroxyaryl carbonate, etc.

Examples of the azobis-based compound may include 1,1′-azobiscyclohexan-1-carbonitrile, 2,2′-azobis(2,4-dimethylvaleronitrile), 2,2,-azobis(methylisobutyrate), 2,2′-azobis(4-methoxy-2,4-dimethylvaleronitrile), α,α′-azobis(isobutylnitrile), 4,4′-azobis(4-cyanovaleric acid), etc.

The photoinitiator may be used together with a photosensitizer that causes a chemical reaction by absorbing light and thus becoming an excited state and then transferring the energy of light. Examples of the photosensitizer may include tetraethylene glycol bis-3-mercaptopropionate, pentaerythritol tetrakis-3-mercaptopropionate, dipentaerythritol tetrakis-3-mercaptopropionate, etc.

The photoinitiator may be included in an amount of 0.01 wt % to 10 wt %, and preferably 0.5 wt % to 8 wt %, based on 100 wt % of the encapsulating composition.

When the photoinitiator is included within the above-described range, excellent film hardness can be obtained, excellent reliability can be obtained because curing occurs sufficiently during the photocuring process, and outgassing can be prevented due to an unreacted initiator.

The photoinitiator can have an absorption spectrum at an active rays of 254 nm to 450 nm.

In still another aspect of the present disclosure, an encapsulating film prepared by applying and coating an encapsulating composition; and photocuring may be provided.

The encapsulating film is preferably prepared by applying and coating an encapsulating composition of the present disclosure using an inkhead that ink-jets with a drop size of 2 picoliters (pL) to 40 picoliters (pL).

In the photocuring step of the encapsulating composition, curing may be achieved by irradiating light in the wavelength range of 254 nm to 450 nm at an intensity of 10 mW/cm² to 500 mW/cm² for 1 to 50 seconds.

The encapsulating layer film prepared by including the photocuring step may have low permittivity and excellent film hardness.

It is preferable that the thickness of the encapsulating film is 3 μm to 15 μm.

The transmittance of the encapsulating film at a wavelength of 550 nm may be 90% to 99%, and preferably 93% to 99%.

The encapsulating film may have a permittivity of 0.1 F/m to 3.2 F/m at a frequency of 1 kHz to 300 kHz, and may preferably have a permittivity of 0.1 F/m to 3.0 F/m at a frequency of 1 kHz to 300 kHz.

The encapsulating film may preferably have a permittivity of 0.1 F/m to 3.2 F/m at a frequency of 1 kHz, a permittivity of 0.1 F/m to 3.2 F/m at a frequency of 100 kHz, or a permittivity of 0.1 F/m to 3.2 F/m at a frequency of 300 kHz, and more preferably have a permittivity of 0.1 F/m to 3.0 F/m at a frequency of 1 kHz, a permittivity of 0.1 F/m to 3.0 F/m at a frequency of 100 kHz, or a permittivity of 0.1 F/m to 3.0 F/m at a frequency of 300 kHz.

The encapsulating film may have a modulus of 1,000 MPa to 5,000 MPa, preferably 1,100 MPa to 4,000 MPa, and more preferably 1,100 MPa to 3,500 MPa.

In still another aspect of the present disclosure, a display including an encapsulating film may be provided.

The display device may include a light-emitting diode. The light-emitting diode may include an organic light-emitting diode (OLED) or an inorganic light-emitting diode (ILED), but is not limited thereto.

The light-emitting diode may include a cathode electrode, an anode electrode, and an intermediate layer positioned between the cathode electrode and the anode electrode, and the intermediate layer may include the above-described light-scattering thin film. The light-emitting diode may additionally include one or more of functional layers, such as a hole injection layer, a hole transport layer, an electron injection layer, an electron transport layer, a light-emitting layer, and an organic barrier layer.

In describing the display devices according to the Examples of the present disclosure, details regarding an encapsulating composition are the same as those described for the encapsulating compositions according to Examples of the present disclosure described above, unless specifically described otherwise, and thus are omitted herein. Since the encapsulating compositions according to the Examples of the present disclosure exhibit low permittivity and excellent film hardness characteristics, electroluminescent diodes including the same can have a highly-sensitive touch sensor.

In still another aspect, according to the Examples of the present disclosure, an electronic device, which includes a display device including an optical film and a control unit for driving the display device, is provided.

In describing the electronic devices according to the Examples of the present disclosure, details regarding the display device are the same as those described for the display devices according to the Examples of the present disclosure described above, unless specifically described otherwise, and thus are omitted herein.

The electronic device may include, for example, a display device, a lighting device, a solar cell, a portable or mobile terminal (e.g., a smart phone, a tablet, a PDA, an electronic dictionary, a PMP, etc.), a navigation terminal, a game machine, various TV sets, various computer monitors, etc., but is not limited thereto, and may include any type of device as long as it includes the component(s).

Hereinafter, the Preparation Examples of preparing the encapsulating composition and a method of preparing the encapsulating film according to the present disclosure will be described in detail, but the present disclosure is not limited to the following Examples.

### I. Preparation of Encapsulating Composition

Encapsulating compositions were prepared with the composition shown in Table 1 below.

Specifically, an initiator was dissolved in the photocurable monomer of Formula 1 above and the photocurable monomer of Formula 2 above, and other additives were added thereto, and the mixture was stirred at room temperature. Subsequently, the product was filtered to remove impurities, thereby preparing an encapsulating composition.

TABLE 1

| | Com- | Com- | Com- | Com- | Com- | Com- |
|---|---|---|---|---|---|---|
| | par- | par- | par- | par- | par- | par- |
| | ative | ative | ative | ative | ative | ative |
| | Exam- | Exam- | Exam- | Exam- | Exam- | Exam- |
| | ple | ple | ple | ple | ple | ple |
| | 1 | 2 | 3 | 4 | 5 | 6 |
| M122 | 37.2 | 37.2 | | | | |
| (Miwon Specialty | | | | | | |
| Chemical) | | | | | | |
| M200 (Miwon | 55.8 | | 55.8 | | 55.8 | |
| Specialty | | | | | | |
| Chemical) | | | | | | |
| A-NODN′ | | 55.8 | | 55.8 | | 55.8 |
| (Shin-Nakamura | | | | | | |
| Chemical) | | | | | | |
| M1142 | | | 37.2 | 37.2 | | |
| (Miwon Specialty | | | | | | |
| Chemical) | | | | | | |
| M1140 (Miwon | | | | | 37.2 | 37.2 |
| Specialty | | | | | | |
| Chemical) | | | | | | |
| TPO (BASF) | 7.0 | 7.0 | 7.0 | 7.0 | 7.0 | 7.0 |

TABLE 2

| | Example | Example | Example | Example | Example | Example |
|---|---|---|---|---|---|---|
| | 1 | 2 | 3 | 4 | 5 | 6 |
| A-NODN | 55.8 | 55.8 | 55.8 | 55.8 | 55.8 | 55.8 |
| (Shin-Nakamura | | | | | | |
| Chemical) | | | | | | |
| T-4 | 37.2 | | | | | |
| T-5 | | 37.2 | | | | |
| T-8 | | | 37.2 | | | |
| T-16 | | | | 37.2 | | |
| T-28 | | | | | 37.2 | |
| T-29 | | | | | | 37.2 |
| TPO (BASF) | 7.0 | 7.0 | 7.0 | 7.0 | 7.0 | 7.0 |

TABLE 3

| | Example | Example | Example | Example | Example | Example |
|---|---|---|---|---|---|---|
| | 7 | 8 | 9 | 10 | 11 | 12 |
| A-NODN | 55.8 | 55.8 | 55.8 | 55.8 | 55.8 | 55.8 |
| (Shin-Nakamura | | | | | | |
| Chemical) | | | | | | |
| T-40 | 37.2 | | | | | |
| T-41 | | 37.2 | | | | |
| T-46 | | | 37.2 | | | |
| T-47 | | | | 37.2 | | |
| T-49 | | | | | 37.2 | |
| T-50 | | | | | | 37.2 |
| TPO (BASF) | 7.0 | 7.0 | 7.0 | 7.0 | 7.0 | 7.0 |

TABLE 4

| | Example | Example | Example | Example | Example | Example |
|---|---|---|---|---|---|---|
| | 1-1 | 2-1 | 3-1 | 4-1 | 5-1 | 6-1 |
| A-NODN | 55.8 | 55.8 | 55.8 | 55.8 | 55.8 | 55.8 |
| (Shin-Nakamura | | | | | | |
| Chemical) | | | | | | |
| T-4 | 37.2 | | | | | |
| T-5 | | 37.2 | | | | |
| T-8 | | | 37.2 | | | |
| T-16 | | | | 37.2 | | |
| T-28 | | | | | 37.2 | |
| T-29 | | | | | | 37.2 |
| TPO (BASF) | 7.0 | 7.0 | 7.0 | 7.0 | 7.0 | 7.0 |
| Hallow silica | 2 | 2 | 2 | 2 | 2 | 2 |
| (70 nm, KC Tech) | | | | | | |

TABLE 5

| | Example | Example | Example | Example | Example | Example |
|---|---|---|---|---|---|---|
| | 7-1 | 8-1 | 9-1 | 10-1 | 11-1 | 12-2 |
| A-NODN | 55.8 | 55.8 | 55.8 | 55.8 | 55.8 | 55.8 |
| (Shin-Nakamura | | | | | | |
| Chemical) | | | | | | |
| T-40 | 37.2 | | | | | |
| T-41 | | 37.2 | | | | |
| T-46 | | | 37.2 | | | |
| T-47 | | | | 37.2 | | |
| T-49 | | | | | 37.2 | |
| T-50 | | | | | | 37.2 |
| TPO (BASF) | 7.0 | 7.0 | 7.0 | 7.0 | 7.0 | 7.0 |
| Hallow silica | 2 | 2 | 2 | 2 | 2 | 2 |
| (70 nm, KC Tech) | | | | | | |

The photocurable monomers and initiators used in Comparative Examples and Examples above are as follows. As a photocurable monomer including an alkylene group having 6 or more carbon atoms represented by Formula 1 above, lauryl acrylate (M122/Miwon Specialty Chemical), 1,6-hexanediol diacrylate (M200/Miwon Specialty Chemical), 1,9-nonaendiol diacrylate (A-NODN/Shin-Nakamura Chemical) were used; isobornyl acrylate (M1140/Miwon Specialty Chemical) as a photocurable monomer including an aliphatic ring represented by Formula 2 above; biphenyl oxyethyl acrylate as a photocurable monomer having aromatic hydrocarbon (M1142/Miwon Specialty Chemical); as combinations of these, acrylateoxyacrylateT-4 (2-((1,2,3,3a,4,5-hexahydro-1,3-methanopentalen-2-yl)oxy)acrylatemethacrylateethyl methacrylate), T-5 (2-(1,2,3,3a,4,5-hexahydro-1,3-methanopentalen-2-yl)aminoyl)amino)acrylatemethacrylateethyl methacrylate), T-8 (1,2,3,3a,4,6a-hexahydropentalen-2-yl acrylate), T-16 (3a,4,5,6,7,7a-hexahydro-1H-4,7-methanoinden-6-yl acrylate), T-28 (2-((3a,4,5,6,7,7a-hexahydro-1H-4,7-methanoinden-6-yl)oxy)ethyl acrylate), T-29 (2-((3a,4,5,6,7,7a-hexahydro-1H-4,7-methanoinden-6-yl)oxy)acrylatemethacrylateethyl methacrylate), T-40 (2-((3a,4,5,6,7,7a-hexahydro-1H-4,7-methanoinden-6-yl)aminoyl)amino)ethyl acetate), T-41 (2-((3a,4,5,6,7,7a-hexahydro-1H-4,7-methanoinden-6-yl)aminoyl)amino)acrylatemethacrylateethyl methacrylate), T-46 (2-((2-((3a,4,5,6,7,7a-hexahydro-1H-4,7-methanoinden-5-yl)aminoyl)amino)ethyl)amino)ethyl acrylate), T-47 (2-(2-(2-((3a,4,5,6,7,7a-hexahydro-1H,4,7-methanoinden-5-yl)oxy-ethoxy-ethoxy)ethyl acrylate), T-49 (2-((2-((2-((3a,4,5,6,7,7a-hexahydro-1H-4,7-methanoinden-6-yl)aminoyl)amino)ethyl)amino)ethyl)amino)ethyl)amino)ethyl) acrylate), and T-50 (14-((3a,4,5,6,7,7a-hexahydro-1H-4,7-methanoinden-6-yl)oxy-3,6,9,12-tetraoxatetradecylacrylate) were used, and a phosphorus-based initiator (TPO/BASF [symbol] ) was used. The compositions of Examples 1-1 to 12-1 were prepared by adding hallow silica to each of their compositions, which are identical to those of Examples 1 to 12, and the permittivity, hardness, and modulus of the resulting compositions were measured.

The encapsulating composition of Comparative Example 1 was prepared by adding 7.0 g of an initiator, 37.2 g of lauryl acrylate (M122), and 55.8 g of hexanediol diacrylate (M200) to a 125 mL brown polypropylene bottle and mixing them at room temperature for 3 hours using a shaker. In the same manner as in Comparative Example 1, the composition of each of Comparative Examples 2 to 6, Examples 1 to 12, and Examples 1-1 to 12-1 were prepared using the compositions having the same components and contents as described in Table 1.

Permittivity, hardness and modulus were measured under the analysis conditions below.

### II. Preparation of Encapsulating Film and Organic Barrier Layer

The method for preparing an organic barrier layer using the ink-jet encapsulating composition is as follows.

### 1) Application and Coating Steps

An organic barrier layer may be formed by a combination of application (coating), curing, etc. of an encapsulating composition for an organic light-emitting diode in the Examples of the present disclosure. For example, the encapsulating composition is injected into an ink-jet head (Konica Minolta) capable of dropping 2 pL to 40 pL, and coated to a thickness of 3 μm to 15 μm to form a thin film.

### (2) Photocuring Step

The coated thin film of an encapsulating composition may be cured by irradiating light in a wavelength range of 254 nm to 450 nm at an intensity of 10 mW/cm² to 500 mW/cm² for 1 to 50 seconds.

### (3) Measurement of Permittivity

After the encapsulating film is prepared to a thickness of 11 μm on a 50 mm×50 mm substrate, a platinum electrode is coated to a thickness of 0.1 μm over the same area as the encapsulating film to prepare a specimen. As a measuring device, LCR meter E4980A (Keysight Technologies) is used to measure CP values at 1 Keysight, 100 Keysight, and 300 kHz, and then permittivity is calculated therefrom.

### (4) Measurement of Hardness and Modulus

The modulus of the cured encapsulating film was measured at a loading force (2 inN), a loading time (10 sec), and a creep time (5 sec) using a nanoindenter HM2000 (FISCHERSCOPE) as the Vickers indenter.

TABLE 6

| | | Permittivity | Permittivity | Permittivity | |
|---|---|---|---|---|---|
| | Modulus | (1 kHz) | (100 kHz) | (300 kHz) | Hardness |
| | [Mpa] | [F/m] | [F/m] | [F/m] | [N/mm] |
| Comparative | 759.44 | 2.74 | 2.70 | 2.68 | 149.21 |
| Example 1 | | | | | |
| Comparative | 712.19 | 2.71 | 2.67 | 2.64 | 150.44 |
| Example 2 | | | | | |
| Comparative | 1192.79 | 3.38 | 3.29 | 3.21 | 167.16 |
| Example 3 | | | | | |
| Comparative | 1075.33 | 3.30 | 3.11 | 3.05 | 158.39 |
| Example 4 | | | | | |
| Comparative | 1153.91 | 3.27 | 3.13 | 3.02 | 174.58 |
| Example 5 | | | | | |
| Comparative | 1098.64 | 3.25 | 3.07 | 3.00 | 176.96 |
| Example 6 | | | | | |
| Example 1 | 1731.43 | 2.87 | 2.77 | 2.74 | 201.82 |
| Example 2 | 1963.73 | 2.86 | 2.74 | 2.71 | 200.25 |
| Example 3 | 2001.47 | 2.78 | 2.64 | 2.63 | 208.11 |
| Example 4 | 1866.62 | 2.77 | 2.70 | 2.69 | 201.54 |
| Example 5 | 1885.96 | 2.71 | 2.68 | 2.59 | 207.49 |
| Example 6 | 1955.77 | 2.84 | 2.77 | 2.61 | 216.17 |
| Example 7 | 1810.21 | 2.74 | 2.66 | 2.54 | 224.40 |
| Example 8 | 1922.26 | 2.75 | 2.64 | 2.41 | 219.74 |
| Example 9 | 1972.95 | 2.81 | 2.73 | 2.58 | 220.96 |
| Example 10 | 1899.87 | 2.88 | 2.81 | 2.76 | 238.09 |
| Example 11 | 1609.14 | 2.90 | 2.84 | 2.79 | 218.60 |
| Example 12 | 1569.45 | 2.96 | 2.90 | 2.82 | 210.47 |
| Example 1-1 | 1770.41 | 2.67 | 2.67 | 2.64 | 237.62 |
| Example 2-1 | 1993.10 | 2.66 | 2.64 | 2.61 | 234.49 |
| Example 3-1 | 2091.71 | 2.58 | 2.54 | 2.53 | 228.73 |
| Example 4-1 | 1892.68 | 2.57 | 2.60 | 2.59 | 241.66 |
| Example 5-1 | 1901.44 | 2.51 | 2.58 | 2.51 | 238.54 |
| Example 6-1 | 1976.06 | 2.64 | 2.67 | 2.55 | 250.07 |
| Example 7-1 | 1887.17 | 2.64 | 2.56 | 2.50 | 251.40 |
| Example 8-1 | 1950.34 | 2.55 | 2.54 | 2.47 | 247.34 |
| Example 9-1 | 2000.06 | 2.51 | 2.53 | 2.48 | 264.16 |
| Example 10-1 | 1924.25 | 2.58 | 2.61 | 2.56 | 262.33 |
| Example 11-1 | 1652.98 | 2.70 | 2.74 | 2.69 | 230.79 |
| Example 12-1 | 1619.49 | 2.76 | 2.70 | 2.62 | 224.97 |

As a result of confirming the encapsulating material compositions after photocuring, the following was confirmed: in Formula 1, the mononers includes 6 to 9 carbon; in Comparative Examples 1 and 2, in which a monomers including 12 carbon was used instead of Formula 2, the compositions showed low dielectric properties but a modulus of 1,000 Mpa or less; in Comparative Examples 3 and 4, in which aromatic hydrocarbons were used instead of Formula 2, the compositions showed modulus properties which were secured at 1,000 Mpa or more, but permittivity was measured to be 3.2 F/m or more. In Comparative Examples 5 and 6, in which monomers including an aliphatic ring group were used, the compositions showed modulus properties which were secured at 1,000 Mpa or more, but permittivity was measured to be 3.2 F/m or more.

It was confirmed that in Examples 1 to 12, in which the compositions include Formula 1 including 6 to 9 carbon, an aliphatic ring group of Formula 2, and a monomer having at least one double bond, the permittivity was shown to be 3.2 F/m or less and the modulus was shown to be 1,000 Mpa or more.

Additionally, it was confirmed that when one or more double bonds are in Formula 2 included, the curing rate was increased, thus showing an increase of the modulus by 700 MPa or more compared to Comparative Examples 4 to 6, and as the content of ethylene oxide in Formula 2 increased, the permittivity slightly was increased but the modulus was slightly decreased.

Compared to Examples 1 to 12, as a result of confirming Examples 1-1 to 12-1 including hollow silica particles, it was confirmed that as inorganic particles were included, the modulus and surface hardness tended to increase in the direction of becoming harder, while the permittivity tended to decrease.

The above description is merely illustrative of the present disclosure, and those skilled in the art to which the present disclosure pertains will be able to make various modifications without departing from the essential characteristics of the present disclosure.

Accordingly, the embodiments disclosed in this specification are for illustrative purposes only and are not intended to limit the present disclosure, and the spirit and scope of the present disclosure are not limited by these embodiments. The scope of protection of the present disclosure should be interpreted in accordance with the claims, and all technologies within the scope equivalent thereto should be interpreted as being included in the scope of rights of the present disclosure.

1. An encapsulating composition comprising a photoinitiator; a first photocurable monomer represented by Formula 1; and a second photocurable monomer represented by Formula 2:
Y₁—X₁—Y₂, [Formula 1]
wherein X₁ is a C₂-C₃₀ alkylene group, and Y₁ and Y₂ are Formula 3, 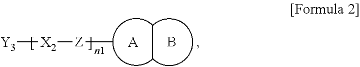
wherein Y₃ is Formula 3, Z is —O— or a —NH— group, X₂ is a C₁-C₃₀ alkylene group, A is a C₃-C₃₀ alicyclic group, B is a ring group comprising at least one double bond of C₃-C₃₀, A ring and B ring are fused together, and n₁ is an integer of 0 to 5, 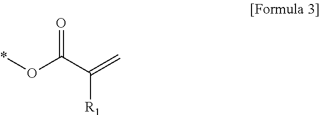
wherein * is a connection part, and R₁ is hydrogen or a methyl group, and
the X₁, X₂, Y₁ to Y₃, and R₁ may each be further substituted with one or more substituents selected from the group consisting of deuterium; a halogen; a C₁-C₃₀ alkyl group; a boron group; a germanium group; a cyano group; an amino group; a nitro group; a C₁-C₃₀ alkylthio group; a C₁-C₃₀ alkoxy group; a fluorenyl group; a C₂-C₃₀ heterocyclic group including at least one heteroatom among O, N, S, Si, and P; a C₃-C₃₀ alicyclic group; and a combination thereof; and may form a ring with a neighboring substituent(s).

2. The encapsulating composition of claim 1, wherein the first photocurable monomer is selected from the group consisting of 1,2-ethandiol diacrylate, 1,3-propanediol diacrylate, 1,4-butanediol diacrylate, 1,5-pentanediol diacrylate, 1,6-hexanediol diacrylate, 1,7-heptanediol diacrylate, 1,8-octanediol diacrylate, 1,9-nonaendiol diacrylate, 1,10-decanediol diacrylate, 1,11-undecanediol diacrylate, 1,12-dodecanediol diacrylate, 1,13-tridecanediol diacrylate, 1,14-tetradecanediol diacrylate, 1,15-pentadecanediol diacrylate, 1,2-ethandiol dimethacrylate, 1,3-propanediol dimethacrylate, 1,4-butanediol dimethacrylate, 1,5-pentanediol dimethacrylate, 1,6-hexanediol dimethacrylate, 1,7-heptanediol dimethacrylate, 1,8-octanediol dimethacrylate, 1,9-nonaendiol dimethacrylate, 1,10-decanediol dimethacrylate, 1,11-undecanediol dimethacrylate, 1,12-dodecanediol dimethacrylate, 1,13-tridecanediol dimethacrylate, 1,14-tetradecanediol dimethacrylate, 1,15-pentadecanediol dimethacrylate, 2,3-propanediol diacrylate, 2,4-butanediol diacrylate, 3,4-butanediol diacrylate, 2,5-pentanediol diacrylate, 4,5-pentanediol diacrylate, 2,6-hexanediol diacrylate, 4,6-hexanediol diacrylate, 2,7-heptanediol diacrylate, 5,7-heptanediol diacrylate, 2,8-octanediol diacrylate, 6,8-octanediol diacrylate, 2,9-nonaendiol diacrylate, 7,9-nonaendiol diacrylate, 2,10-decanediol diacrylate, 8,10-decanediol diacrylate, 3,12-dodecanediol diacrylate, 11,12-dodecanediol diacrylate, 5,15-pentadecanediol diacrylate, 10,15-pentadecanediol diacrylate, 2,3-propanediol dimethacrylate, 2,4-butanediol dimethacrylate, 3,4-butanediol dimethacrylate, 2,5-pentanediol dimethacrylate, 4,5-pentanediol dimethacrylate, 2,6-hexanediol dimethacrylate, 4,6-hexanediol dimethacrylate, 2,7-heptanediol dimethacrylate, 5,7-heptanediol dimethacrylate, 2,8-octanediol dimethacrylate, 6,8-octanediol dimethacrylate, 2,9-nonaendiol dimethacrylate, 7,9-nonaendiol dimethacrylate, 2,10-decanediol dimethacrylate, 8,10-decanediol dimethacrylate, 2,12-dodecanediol dimethacrylate, 6,12-dodecanediol dimethacrylate, 10,12-dodecanediol dimethacrylate, 2,15-pentadecanediol dimethacrylate, 7,15-pentadecanediol dimethacrylate, 12,15-pentadecanediol dimethacrylate, and a combination thereof.

3. The encapsulating composition of claim 1, wherein A ring of the second photocurable monomer comprises an alicyclic group selected from three- to six-membered rings; B ring comprises a carbon ring group selected from three- to six-membered rings comprising at least one double bond within the ring; and A ring and B ring may be further substituted with one or more substituents selected from a C₁-C₃₀ alkyl group, and may form a ring with a neighboring substituent(s).

4. The encapsulating composition of claim 1, wherein the second photocurable monomer is selected from the group consisting of the following T-1 to T-50 and a combination thereof:

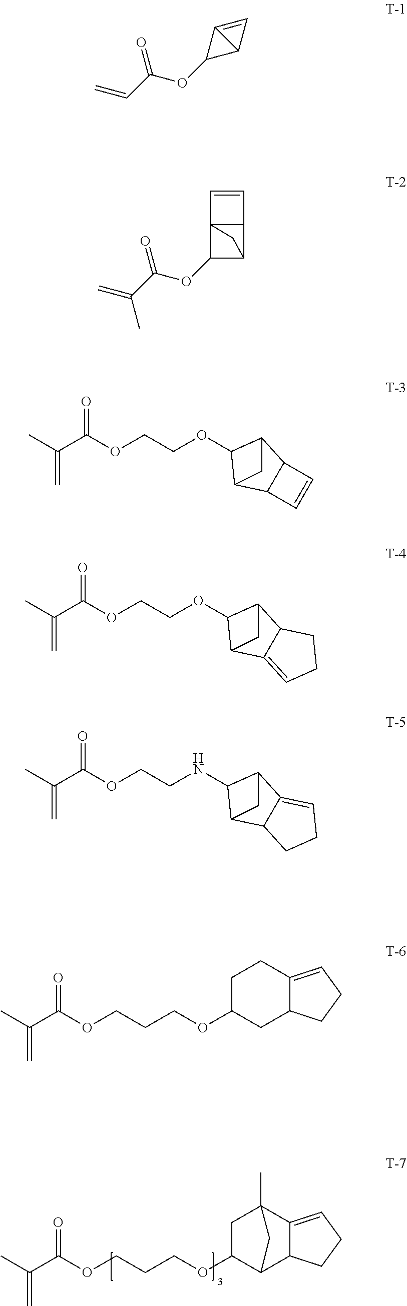

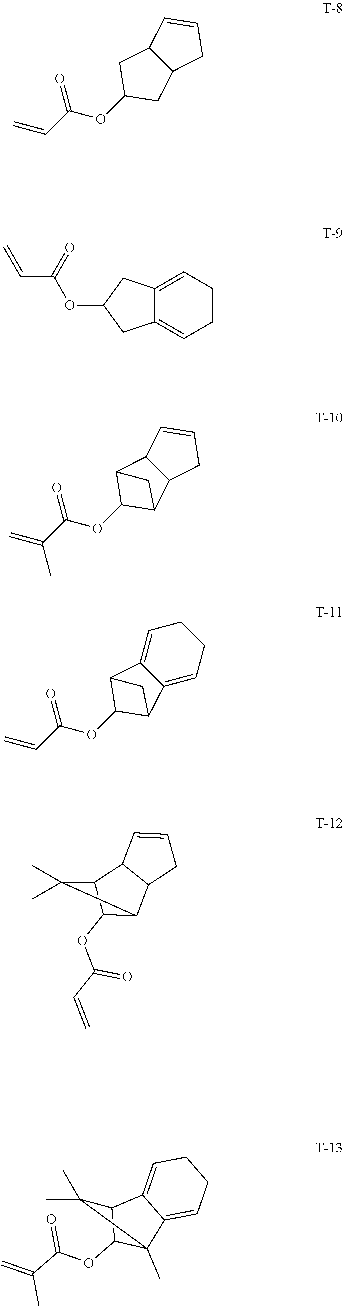 [SMILES: C=CC(=O)OC1CC2C=CCC2C1 ; C=CC(=O)OC1CC2=CCCC=C2C1 ; C=C(C)C(=O)OC1C2CC1C1CC=CC12 ; C=CC(=O)OC1C2CC1C1=CCCC=C12 ; C=CC(=O)OC1C2C3C=CCC3C1C2(C)C ; C=C(C)C(=O)OC1C2C3=CCCC=C3C1(C)C2(C)C]

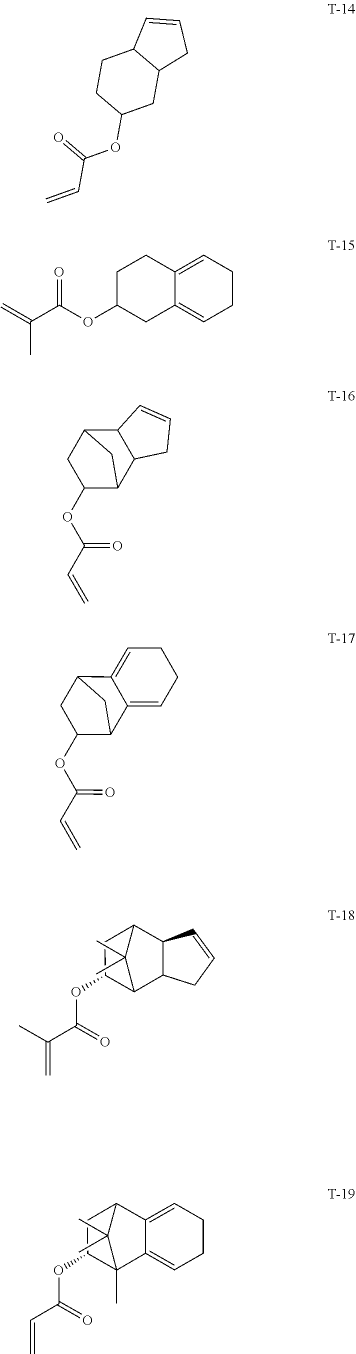

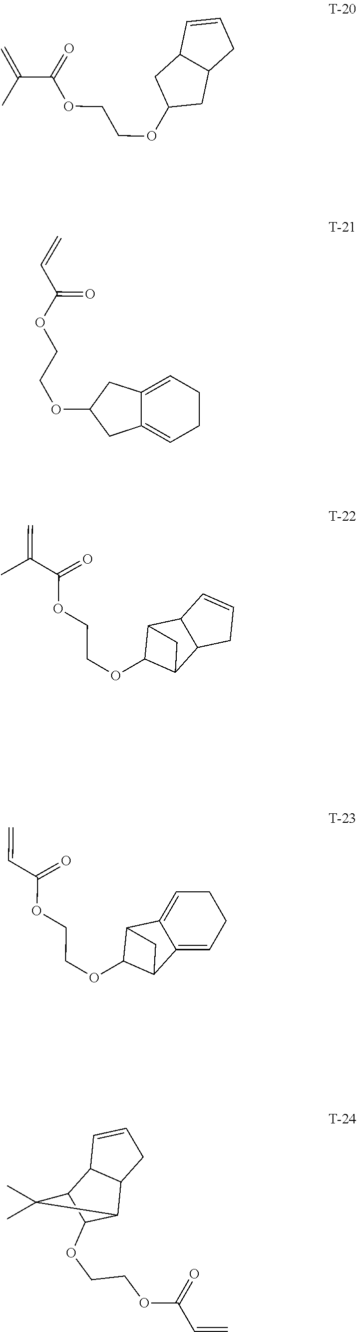 [SMILES: C=C(C)C(=O)OCCOC1CC2C=CCC2C1 ; C=CC(=O)OCCOC1CC2=CCCC=C2C1 ; C=C(C)C(=O)OCCOC1C2CC1C1CC=CC12 ; C=CC(=O)OCCOC1C2CC1C1=CCCC=C12 ; C=CC(=O)OCCOC1C2C3C=CCC3C1C2(C)C]

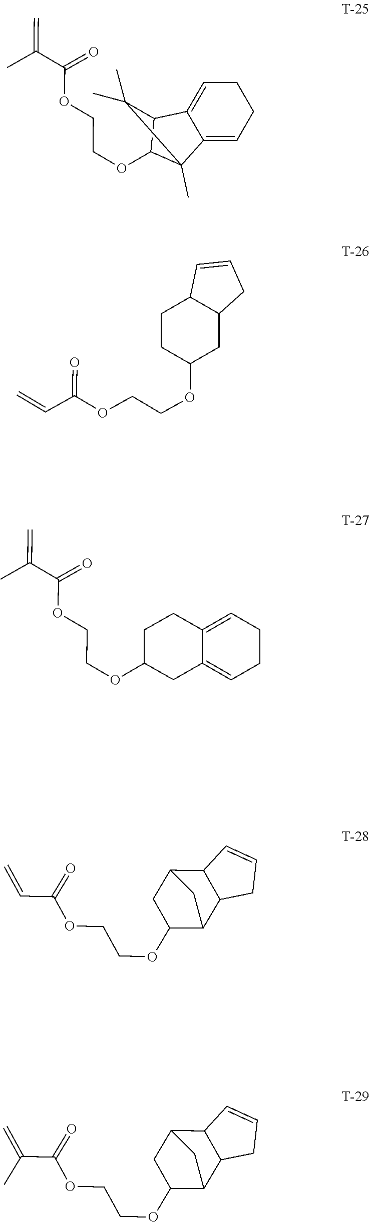 [SMILES: C=C(C)C(=O)OCCOC1C2C3=CCCC=C3C1(C)C2(C)C ; C=CC(=O)OCCOC1CCC2C=CCC2C1 ; C=C(C)C(=O)OCCOC1CCC2=CCCC=C2C1 ; C=CC(=O)OCCOC1CC2CC1C1CC=CC21 ; C=C(C)C(=O)OCCOC1CC2CC1C1CC=CC21]

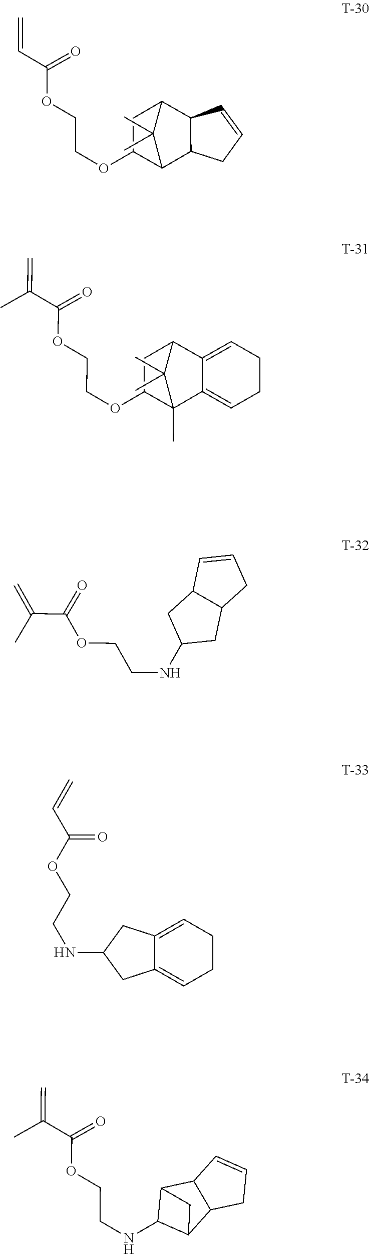

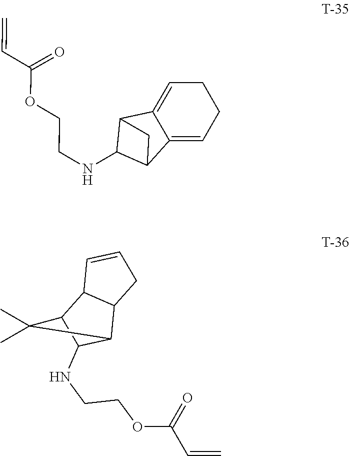 [SMILES: C=CC(=O)OCCNC1C2CC1C1=CCCC=C12 ; C=CC(=O)OCCNC1C2C3C=CCC3C1C2(C)C]

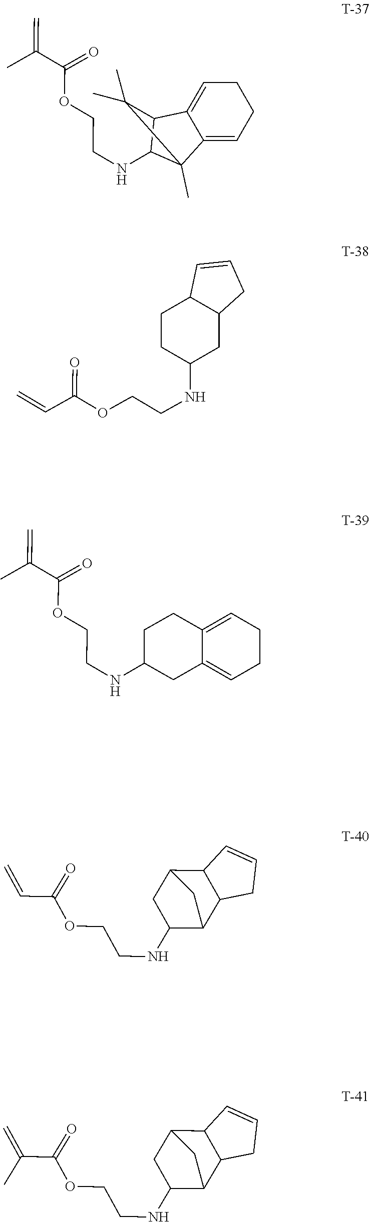 [SMILES: C=C(C)C(=O)OCCNC1C2C3=CCCC=C3C1(C)C2(C)C ; C=CC(=O)OCCNC1CCC2C=CCC2C1 ; C=C(C)C(=O)OCCNC1CCC2=CCCC=C2C1 ; C=CC(=O)OCCNC1CC2CC1C1CC=CC21 ; C=C(C)C(=O)OCCNC1CC2CC1C1CC=CC21]

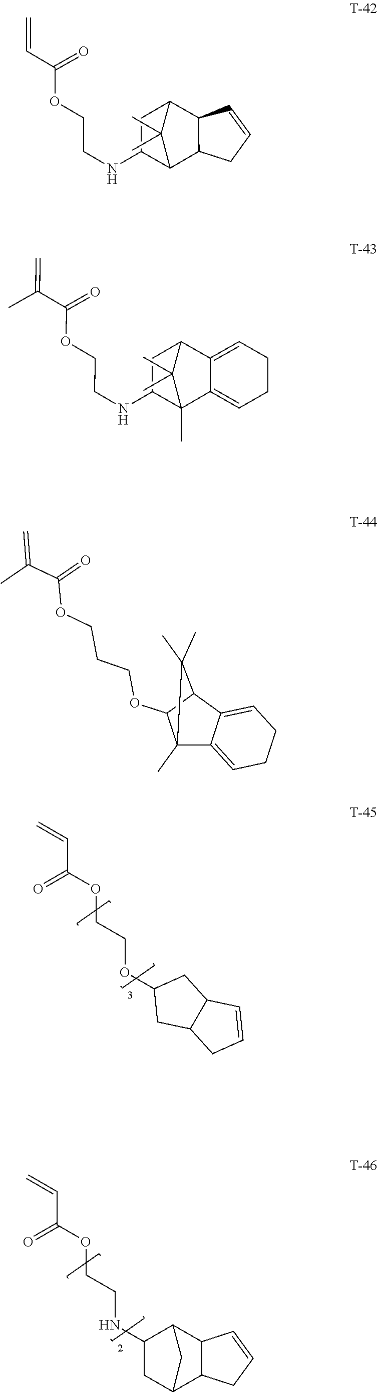

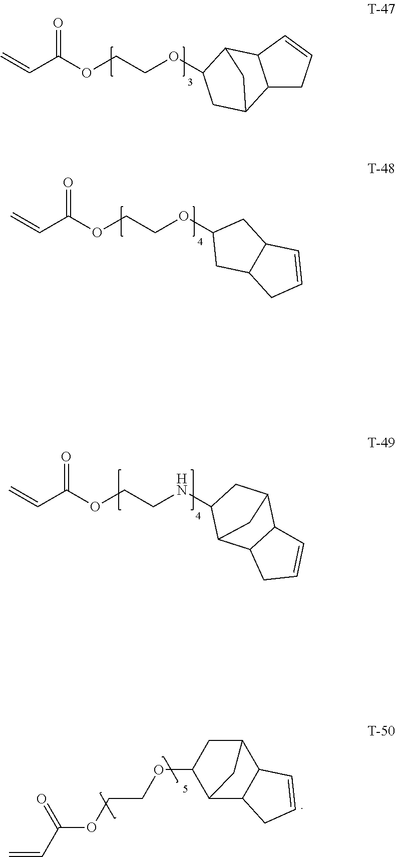

5. The encapsulating composition of claim 1 further comprising hollow silica particles.

6. The encapsulating composition of claim 1 having a surface tension of 20 mN/m to 40 mN/m at 25° C.

7. An encapsulating film prepared by applying and coating; and photocuring of the encapsulating composition of claim 1.

8. The encapsulating film of claim 7, wherein the applying and coating are performed using an inkhead which ink-jets with a drop size of 2 pL to 40 pL.

9. The encapsulating film of claim 7 having a thickness of 3 μm to 15 μm.

10. The encapsulating film of claim 7 having a permittivity of 0.1 F/m to 3.2 F/m at a frequency from 1 kHz to 300 kHz.

11. The encapsulating film of claim 7 having a modulus of 1,000 MPa to 5,000 MPa.

12. The encapsulating film of claim 7 having a transmittance of 90% to 99% at a wavelength of 550 nm.

13. An organic barrier layer comprising the encapsulating composition of claim 1.

14. A display device comprising the organic barrier layer of claim 13.

15. An electronic device comprising the display device of claim 14; and a control unit for driving the display device.
